(19) United States
(12) Patent Application Publication
(10) Pub. No.: US 2026/0190486 A1
(43) Pub. Date: Jul. 2, 2026

(54) DISPLAY DEVICE

(71) Applicant: Guangzhou China Star Optoelectronics Semiconductor Display Technology Co., LTd., Guangzhou (CN)

(72) Inventors: Jun WANG, Guangzhou (CN); Junjie LI, Guangzhou (CN); Lei LIU, Guangzhou (CN); Feng LIU, Guangzhou (CN)

(73) Assignee: Guangzhou China Star Optoelectronics Semiconductor Display Technology Co., LTd., Guangzhou (CN)

(21) Appl. No.: 19/093,014

(22) Filed: Mar. 27, 2025

(30) Foreign Application Priority Data
Dec. 31, 2024 (CN) 202411997294.X

(51) Int. Cl. H10D 86/40; H01L 23/498

(52) U.S. Cl. CPC H10D 86/441; H10W 90/401

(57) ABSTRACT

A display device is provided. The display device includes an array substrate, a support member, and a decorative member. The array substrate includes a pin bonding area. The support member is located in the pin bonding area of the array substrate. The decorative member is connected to the support member and shields the pin bonding area.

### CROSS-REFERENCE TO RELATED APPLICATION

This application claims priority to and the benefit of Chinese Patent Application No. 202411997294.X, filed on Dec. 31, 2024, the disclosure of which is incorporated herein by reference in its entirety.

### TECHNICAL FIELD

The present application relates to the field of display technology, and in particular, to a display device.

### BACKGROUND

With the increasing popularity of display devices, demands on the aesthetic degree of display devices are also increasing. At present, in order to make the appearance of the display device more beautiful and more scientific, the pursuit of a narrow frame for the display device is increasing, and it is hoped that the frame will be as narrow as possible. However, as the frame becomes narrower, the narrowing of the frame encounters a technical bottleneck.

### SUMMARY

Embodiments of the present disclosure provide a display device to reduce the size of the display device to at least partially solve the above technical problem.

In order to achieve the above object, the embodiments of the present disclosure provide a display device. The display device includes an array substrate, one or more support members, and a decorative member. The array substrate includes a pin bonding area. The support member is located in the pin bonding area of the array substrate. The decorative member is connected to the support member and shields the pin bonding area.

Optionally, the one or more support members include one or more magnetic members, and the decorative member is adsorbed to the one or more magnetic members.

Optionally, the magnetic members are fixed to the pin bonding area.

Optionally, the display device further includes a first adhesive layer, and the first adhesive layer is located between the one or more magnetic members and the array substrate.

Optionally, a thickness of the first adhesive layer is less than a thickness of each of the one or more magnetic members.

Optionally, each of the one or more support members includes a second adhesive layer, and the second adhesive layer adheres the decorative member with the array substrate.

Optionally, the array substrate includes a conductive structure located in the pin bonding area; the display device further includes a protective layer, and the protective layer covers the conductive structure and is located between the one or more support members and the array substrate.

Optionally, the display device further includes a plurality of flexible films, the plurality of flexible films are bonded to the pin bonding area, and at least one of the plurality of flexible films is located between the array substrate and one of the one or more support members.

Optionally, the display device further includes an opposite substrate and a first polarizer, and the opposite substrate is disposed opposite to the array substrate. The first polarizer is attached to a surface of the opposite substrate facing away from the array substrate. The pin bonding area extends outwardly relative to the opposite substrate, and the decorative member is further attached to the surface of the opposite substrate facing away from the array substrate and is in contact with the first polarizer.

Optionally, the display device further includes a coating layer. The coating layer is disposed on a surface of the decorative member facing away from the one or more support members, and a color of the coating layer is same as a color of a surface of the first polarizer facing away from the array substrate.

Optionally, a sum of a thickness of the decorative member and a thickness of the coating layer is equal to a thickness of the first polarizer.

Optionally, a thickness of each of the one or more support members is less than a thickness of the opposite substrate.

Optionally, the decorative member includes a strip-like body portion, and the strip-like body portion is fixed to the one or more support members and shields the pin bonding area.

In the display device of some embodiments of the present disclosure, the decorative member is installed on the display device through the support member located in the pin bonding area, thereby reducing the size of the non-display area of the display device.

### BRIEF DESCRIPTION OF THE DRAWINGS

FIG. 1 is a schematic diagram of a planar structure of a display device according to some embodiments of the present disclosure;

FIG. 2 is a schematic diagram of a cross-sectional structure taken along A-A′ line shown in FIG. 1 according to some embodiments of the present disclosure;

FIG. 3 is a schematic diagram of a local structure in which support members of a display device are fixed to a pin bonding area according to some embodiments of the present disclosure;

FIG. 4 is a schematic diagram of another local structure in which support members of a display device are fixed to a pin bonding area according to some embodiments of the present disclosure;

FIG. 5 is a schematic diagram of another cross-sectional structure taken along A-A′ line shown in FIG. 1 according to some embodiments of the present disclosure;

FIG. 6 is a schematic diagram of still another cross-sectional structure taken along A-A′ line shown in FIG. 1 according to some embodiments of the present disclosure.

The reference numerals are listed below:
100. Display Device;
11. Display panel;
12. Array substrate; 12A. Array area; 12B. Pin bonding area; 121. Base; 122. Conductive structure; 123. Bonding pin;
13. Opposite substrate; 131. Opposite base;
14. Backlight module; 141. Optical film; 142. Light source; 143. Backplane; 144. Light-transmitting plate;
21. Support member; 211. First support member; 212. Second support member; 22. Magnetic member; 23. Second adhesive layer;
31. First adhesive layer;
41. Decorative member; 411. Strip-like body portion; 412. First bending portion;
51. Protective layer; 52. Coating layer;
61. Flexible film; 62. Driving unit;
711. First polarizer; 712. Second polarizer;
81. Support frame; 811. Frame body; 812. Support protruding portion.

### DETAILED DESCRIPTION

The technical solutions in the embodiments of the present disclosure will be clearly and completely described below in conjunction with the accompanying drawings in the embodiments of the present disclosure. It is apparent that the embodiments described herein are only some of the embodiments of the present disclosure, but not all of the embodiments of the present disclosure. Based on the embodiments of the present disclosure, all other embodiments obtained by those skilled in the art without making creative efforts fall within the scope of protection of the present disclosure.

Referring to FIG. 1 to FIG. 6, the embodiments of the present disclosure provide a display device 100. The display device 100 includes a display panel 11. The display panel 11 is configured for display. The display panel 11 can be any one of the following: a liquid crystal display panel, an organic light-emitting diode display panel, a quantum dot display panel, a micro light-emitting diode display panel, or a sub-millimeter light-emitting diode display panel. The display panel 11 can also be any one of a flexible display panel, a foldable display panel, a rollable display panel, and a rigid display panel.

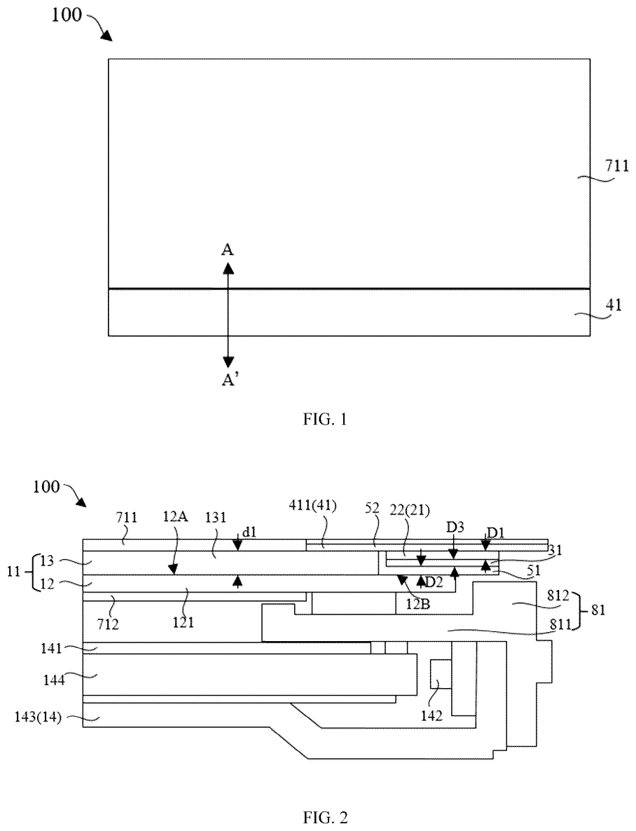

In some embodiments, referring to FIG. 2 to FIG. 6, the display panel 11 includes an array substrate 12. The array substrate 12 includes an array area 12A and a pin bonding area 12B. The array area 12A is adjacent to the pin bonding area 12B.

The array area 12A of the array substrate 12 overlaps with the display area of the display panel 11. The array substrate 12 includes a base 121. The array area 12A is provided with a pixel driving circuit (not shown) and a signal line (not shown) disposed on the base 121, and the signal line is connected to the pixel driving circuit.

The pin bonding area 12B of the array substrate 12 overlaps with the non-display area of the display panel 11.

In some embodiments, referring to FIG. 2, the array substrate 12 includes a conductive structure 122 located in the pin bonding area 12B. The conductive structure 122 transmits the driving signal to the array area 12A.

In some embodiments, the conductive structure 122 can include bonding pins 123. The conductive structure 122 can further include conductive wirings. The bonding pins 123 are connected to a plurality of signal lines (not shown) in the array area 12A. The bonding pin 123 is configured to input the driving signal and output the driving signal to the pixel driving circuit through the signal line, so that the display panel 11 realizes display.

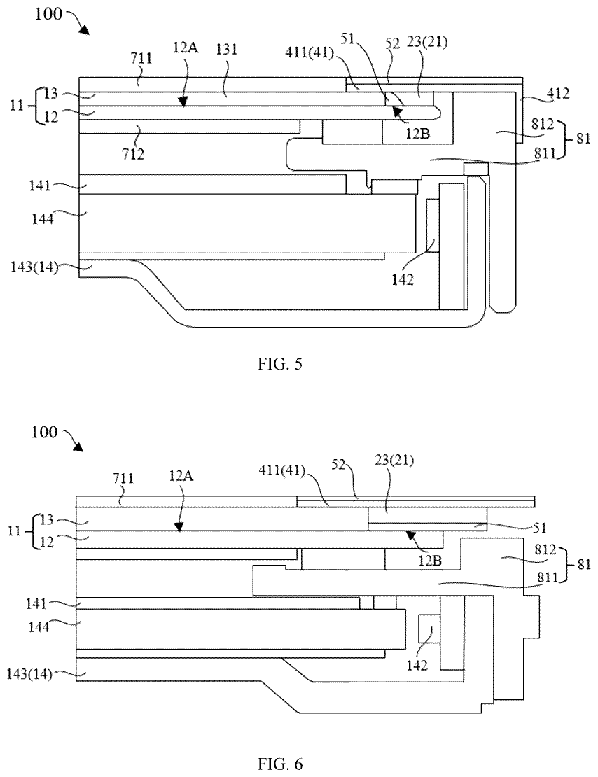

In some embodiments, referring to FIG. 2, FIG. 5 and FIG. 6, the display device 100 further includes a protective layer 51, and the protective layer 51 covers the conductive structure 122. The protective layer 51 plays a role in protecting the conductive structure 122.

In some embodiments, the protective layer 51 can include a moisture-resistant material to alleviate the problem of corrosion to the conductive structure 122 caused by water. A conventional material may be used as the moisture-resistant material.

In some embodiments, the protective layer 51 can also include an oxygen-absorbing material to alleviate the problem of corrosion to the conductive structure 122 caused by oxygen. A conventional material can be used as the oxygen-absorbing material.

In some embodiments, the protective layer 51 can include a protective adhesive layer, for example, an optical protective adhesive such as Tuffy adhesive.

In some embodiments, referring to FIG. 2 to FIG. 6, the display panel 11 further includes an opposite substrate 13. The opposite substrate 13 is disposed opposite to the array substrate 12. The pin bonding area 12B extends outwardly relative to the opposite substrate 13 to facilitate bonding of the flexible film 61 carrying the driving unit 62 to the bonding pins 123 in the pin bonding area 12B.

In some embodiments, the opposite substrate 13 and the array substrate 12 can be connected by a frame adhesive (not shown in the figure).

In some embodiments, a liquid crystal layer (not shown in the figure) is disposed between the opposite substrate 13 and the array substrate 12. In other words, the display panel 11 is a liquid crystal display panel.

In some embodiments, the opposite substrate 13 can include an opposite base 131 and a color film layer (not shown in the figure), and the color film layer is located on the side of the opposite base 131 facing the array substrate 12, that is, the opposite substrate 13 is a color film substrate. In some other embodiments, the opposite substrate 13 can also be an encapsulation substrate.

In some embodiments, referring to FIG. 2, FIG. 5 and FIG. 6, the display device 100 further includes a support frame 81. The support frame 81 includes a frame body 811. The frame body 811 has a frame-like shape, and an opening is provided in the middle of the frame body. The display panel 11 is fixed to the frame body 811. In an exemplary embodiment, in a case where the display panel 11 includes the array substrate 12, the side of the array substrate 12 facing away from the opposite substrate 13 is fixed to the frame body 811 by an adhesive layer. The adhesive layer may include, but is not limited to, a foam adhesive and the like.

In some embodiments, referring to FIG. 2, FIG. 5 and FIG. 6, when the display panel 11 is a liquid crystal display panel, the display device 100 further includes a backlight module 14. The backlight module 14 can include a light-transmitting plate 144 such as a light guiding plate, and the light-transmitting plate 144 is fixed to the side of the frame body facing away from the display panel 11.

In some embodiments, referring to FIG. 2, FIG. 5 and FIG. 6, the backlight module 14 can further include an optical film 141. The optical film 141 is disposed on the light-transmitting plate 144. The optical film 141 can include at least one of a brightness enhancement film and a diffusion film.

In some embodiments, referring to FIG. 2, FIG. 5 and FIG. 6, the backlight module 14 can further include a light source 142. The light source 142 can be located on the side surface of the light-transmitting plate 144. The light source 142 can be located on the side of the light-transmitting plate 144 facing away from the display panel 11.

In some embodiments, referring to FIG. 2, FIG. 5 and FIG. 6, the backlight module 14 can further include a backplane 143. The backplane 143 includes an accommodating space in which the light source 142, the light transmitting plate 144, the optical film 141, and the like are disposed. The support frame 81 is fixed to the backplane 143 to achieve the fixation of the support frame 81, and therefore, the display panel 11 is fixed to the light-emitting side of the backlight module 14.

In some embodiments, referring to FIG. 1 to FIG. 6, the display device 100 further includes a support member 21 and a decorative member 41. The support member 21 is located in the pin bonding area 12B of the array substrate 12. The decorative member 41 is connected to the support member 21 and shields the pin bonding area 12B. In this way, the decorative member 41 plays a role in shielding the pin bonding area 12 B, and is installed on the display device 100 by the support member 21 located in the pin bonding area 12B. That is, the decorative member 41 is installed in the non-display area of the array substrate 12 that needs to be shielded, so as to reduce the size of the non-display area of the display device 100.

In some embodiments, the thickness D1 of the support member 21 is less than the thickness d1 of the opposite substrate 13, thereby reducing the risk that the decorative member 41 on the support member 21 protrudes from the display panel 11, and further reducing the risk that a gap difference is generated between the decorative member 41 on the support member 21 and the display panel 11, and thus improving the appearance of the display panel 11.

In some embodiments, referring to FIG. 2, FIG. 5, and FIG. 6, in a case where the protective layer 51 covers the conductive structure 122, the protective layer 51 is located between the support member 21 and the array substrate 12, thereby reducing the risk of damage to the conductive structure 122 covered by the protective layer 51 caused by the support member 21.

In some embodiments, referring to FIG. 2, in a case where the protective layer 51 covers the conductive structure 122, a portion of the protective layer 51 is further located between the support member 21 and the opposite substrate 13, thereby further improving the protective effect of the protective layer 51 on the conductive structure 122. Further, the risk of damage to the opposite substrate 13 caused by the direct contact between the support member 21 and the opposite substrate 13 is reduced.

In some embodiments, the thickness D2 of the protective layer 51 is less than the thickness D1 of the support member 21, so that the thickness of the support member 21 is thick enough to better play a supporting role.

In some embodiments, the thickness D2 of the protective layer 51 is between 8 microns and 12 microns, which ensures that the protective layer 51 plays a role in protecting the conductive structure 122, and at the same time provides more space for disposing the support member 21.

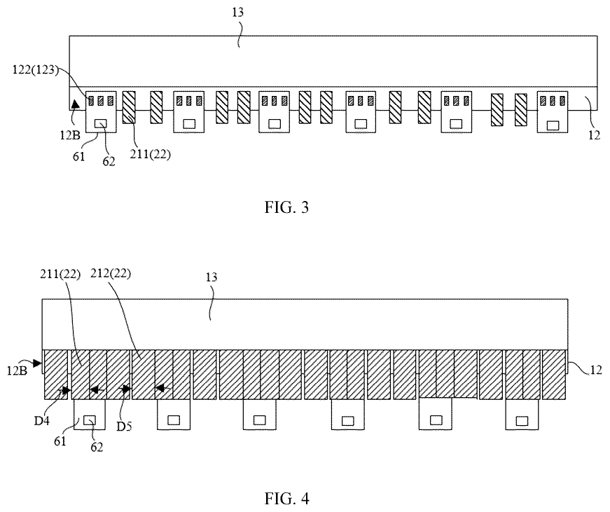

In some embodiments, referring to FIG. 3 and FIG. 4, the display device 100 further includes a flexible film 61. A plurality of flexible films 61 are spaced apart and bonded to the bonding pins 123 of the pin bonding area 12B. Each flexible film 61 is provided with a driving unit 62. The driving unit 62 transmits the driving signal to the bonding pin 123 of the pin bonding area 12B through the flexible film 61, and the bonding pin 123 then transmits the driving signal to the pixel driving circuit in the array area 12A through the signal line.

In some embodiments, referring to FIG. 3 and FIG. 4, the orthographic projection of at least one support member 21 on the array substrate 12 is between adjacent flexible films 61, thereby reducing the risk of damage to the flexible film 61 by the support member 21.

In some embodiments, referring to FIG. 4, at least one flexible film 61 is located between the array substrate 12 and the support member 21. In this way, the support member 21 is disposed on the flexible film 61 to increase the number and the total supporting area of the support member 21, thereby improving the firmness of the support member 21 in fixing the decorative member 41.

In some embodiments, continuing referring to FIG. 4, the plurality of support members 21 include a first support member 211 and a second support member 212. The first support member 211 is disposed on the flexible film 61, and the second support member 212 is disposed between adjacent flexible films 61. Along the arrangement direction of the plurality of flexible films 61, the dimension D4 of the first support member 211 is less than the dimension D5 of the second support member 212. In this way, the first support member 211 can be more flexibly installed on the flexible film 61, and the risk of damage to the flexible film 61 caused by the first support member 211 is reduced.

In some embodiments, referring to FIG. 2 to FIG. 4, the support member 21 includes a magnetic member 22. The decorative member 41 is adsorbed to the magnetic member 22. The decorative member 41 is fixed to the display device 100 by using the magnetic adsorption force of the magnetic member 22, which not only simplifies the installation process of the decorative member 41, but also facilitates the disassembly and replacement of the decorative member 41.

In some embodiments, the magnetic member 22 may be in a strip-like shape.

In some embodiments, the magnetic member 22 includes, but is not limited to, a magnetic material such as a neodymium iron boron magnet.

In some embodiments, referring to FIG. 3 and FIG. 4, a plurality of magnetic members 22 are fixed to the pin bonding area 12B. The size of the plurality of magnetic members 22 is small, so that the plurality of magnetic members 22 can be more flexibly installed on the pin bonding area 12B having a relatively small size. Further, the size of the plurality of magnetic members 22 is small, thereby reducing the risk that the magnetic members 22 are damaged due to having a large size.

In some embodiments, the sizes of at least two magnetic members 22 may be the same along the arrangement direction of the plurality of magnetic members 22 to simplify the formation process of the at least two magnetic members 22. In some other embodiments, the sizes of the at least two magnetic members 22 may be different from each other, thereby improving the flexibility of fixing the at least two magnetic members 22 to the pin bonding area 12B.

In some embodiments, only one magnetic member 22 can be fixed to the pin bonding area 12B. The decorative member 41 is fixed to one magnetic member 22.

In some embodiments, referring to FIG. 2 to FIG. 4, a portion of the magnetic members 22 extend outwardly relative to the pin bonding area 12B, that is, a portion of the magnetic member 22 is located outside the pin bonding area 12B, so as to increase the supporting area of the magnetic member 22 and improve the firmness of the support member 21 in fixing the decorative member 41.

In some embodiments, referring to FIG. 2, the display device 100 further includes a first adhesive layer 31. The first adhesive layer 31 is located between the magnetic member 22 and the array substrate 12, so that the magnetic member 22 is fixed to the pin bonding area 12B of the array substrate 12 by the first adhesive layer 31.

In some embodiments, the thickness D3 of the first adhesive layer 31 is less than the thickness of the magnetic member 22, the thickness of the first adhesive layer 31 is relatively thinner, and the thickness of the magnetic member 22 is relatively thicker, thereby reducing the risk that the magnetic member 22 is damaged due to having a thin thickness.

In some embodiments, the thickness of the first adhesive layer 31 can be 0.02 millimeters to 0.05 millimeters, ensuring that the first adhesive layer 31 has sufficient adhesive strength and providing more layout space for the magnetic member 22.

In some embodiments, the thickness of the magnetic member 22 can be between 0.2 millimeters to 0.4 millimeters, which reduces the risk that the magnetic member 22 is damaged due to having a thin thickness, and while reducing the risk that a gap difference is formed between the decorative member 41 on the magnetic member 22 and the display panel 11 due to the magnetic member 22 being too thick.

In some embodiments, referring to FIG. 5 and FIG. 6, the support member 21 can include a second adhesive layer 23, and the second adhesive layer 23 adheres the decorative member 41 and the array substrate 12. In this way, the decorative member 41 is installed on the display device 100 by the second adhesive layer 23.

In some embodiments, referring to FIG. 5, when the protective layer 51 covers the conductive structure 122 and the protective layer 51 is located in a partial area of the pin bonding area 12B, the second adhesive layer 23 covers the protective layer 51 and the array substrate 12 in the pin bonding area 12B.

In some embodiments, referring to FIG. 6, when the protective layer 51 covers the conductive structure 122 and the protective layer 51 is located on the entire pin bonding area 12B, the second adhesive layer 23 is located between the protective layer 51 and the decorative member 41.

In some embodiments, the second adhesive layer 23 can include a double-sided adhesive layer to ensure that the second adhesive layer 23 provides adhesiveness, while the second adhesive layer 23 also has sufficient mechanical strength to support the decorative member 41. The double-sided adhesive layer includes a base material layer and an adhesive layer located on the base material layer. The substrate layer can include the flexible film 61.

In some embodiments, the thickness of the second adhesive layer 23 is greater than the thickness of the protective layer 51. In this way, it is ensured that the second adhesive layer 23 provides a good supporting effect.

In some embodiments, referring to FIG. 1, FIG. 2, FIG. 5 and FIG. 6, the display device 100 further includes a first polarizer 711. The first polarizer 711 is attached to the surface of the opposite substrate 13 facing away from the array substrate 12. The first polarizer 711 is configured to adjust the display effect of the display device 100.

In some embodiments, referring to FIG. 1, FIG. 2, FIG. 5 and FIG. 6, the display device 100 further includes a second polarizer 712. The display panel 11 is located between the first polarizer 711 and the second polarizer 712. The first polarizer 711 cooperates with the second polarizer 712 to adjust the display effect of the display device 100.

In some embodiments, as shown in FIG. 1, FIG. 2, FIG. 5, and FIG. 6, the decorative member 41 is further attached to the surface of the opposite substrate 13 facing away from the array substrate 12 and is spliced with the first polarizer 711, so that there is no gap between the first polarizer 711 and the decorative member 41, thereby improving the appearance effect of the display device 100.

In some embodiments, the material of the decorative member 41 can include a metal such as stainless steel, so that the decorative member 41 not only plays a decorative role, but also has a certain mechanical strength to reduce the risk of damage under the action of external force.

In some embodiments, referring to FIG. 2, FIG. 5 and FIG. 6, the display device 100 further includes a coating layer 52. The coating layer 52 is located on the surface of the decorative member 41 facing away from the support member 21. The color of the coating layer 52 is the same as the color of the surface of the first polarizer 711 facing away from the array substrate 12. The appearance of the coating layer 52 tends to be the same as the appearance of the first polarizer 711, so that the display panel 11 can achieve a frameless effect.

In some embodiments, referring to FIG. 2, FIG. 5, and FIG. 6, the sum of the thickness of the decorative member 41 and the thickness of the coating layer 52 is equal to the thickness of the first polarizer 711. It is ensured that there is no gap difference between the coating layer 52 and the first polarizer 711 to achieve a better product appearance effect.

In some embodiments, the thickness of the decorative member 41 is greater than the thickness of the coating layer 52. It is ensured that the decorative member 41 has a relatively large thickness, so that the decorative member has sufficient mechanical strength to play a protective role.

In some embodiments, the decorative member 41 includes a strip-like body portion 411, and the strip-like body portion 411 is fixed to the support member 21 and shields the pin bonding area 12B. In this way, the decorative member 41 can be used to replace the front frame in the related art, so as to play a role in shielding the pin bonding area 12B of the array substrate 12, and further eliminate the gap difference between the pin bonding area and the display panel 11.

In some embodiments, referring to FIG. 2, FIG. 5, and FIG. 6, the decorative member 41 can further shield the support frame 81.

In some embodiments, referring to FIG. 2 and FIG. 6, the decorative member 41 and the support frame 81 are spaced apart.

In some embodiments, referring to FIG. 5, the support frame 81 further includes a support protruding portion 812, and the support protruding portion 812 is located on the frame body 811. The strip-like body portion 411 is further fixed to the supporting protruding portion 812 to increase the supporting area for the decorative member 41.

In some other embodiments, referring to FIG. 5, the decorative member 41 can further include a first bending portion 412. The first bending portion 412 is bent with respect to the strip-like body portion 411 toward a direction facing away from the coating layer 52. The first bending portion 412 can limit the movement of the decorative member 41.

In some embodiments, referring to FIG. 5, the first bending portion 412 can be located on the side of the support frame 81 facing away from the opening of the support frame 81. In this way, the first bending portion 412 can limit the movement of the decorative member 41.

In some other embodiments, the decorative member 41 can further include a second bending portion (not shown in the figure), and the second bending portion is connected to the first bending portion 412. The strip-like body portion 411, the first bending portion 412, and the second bending portion have a U-shape as a whole.

To sum up, in the display device of the embodiments of the present disclosure, the decorative member is installed on the display device through the support member located in the pin bonding area, thereby reducing the size of the non-display area of the display device.

The description of the above embodiments is merely provided to help understand the technical solution and the core idea of the present disclosure. It should be understood that, a person skilled in the art may modify the technical solutions recorded in the foregoing embodiments, or to equivalently replace some of the technical features. However, these modifications or replacements do not cause the essence of the corresponding technical solution to depart from the scope of the technical solution of each embodiment of the present disclosure.

What is claimed is:

1. A display device comprising:
an array substrate comprising a pin bonding area;
one or more support members located in the pin bonding area of the array substrate; and
a decorative member connected to the one or more support members and shielding the pin bonding area.

2. The display device according to claim 1, wherein the one or more support members comprise one or more magnetic members, and the decorative member is adsorbed to the one or more magnetic members.

3. The display device according to claim 2, wherein the magnetic members are fixed to the pin bonding area.

4. The display device according to claim 2, wherein a portion of the one or more magnetic members extend outwardly relative to the pin bonding area.

5. The display device according to claim 2, further comprising:
a first adhesive layer disposed between the one or more magnetic members and the array substrate.

6. The display device according to claim 5, wherein a thickness of the first adhesive layer is less than a thickness of each of the one or more magnetic members.

7. The display device according to claim 1, wherein each of the one or more support members comprises a second adhesive layer, and the second adhesive layer adheres the decorative member with the array substrate.

8. The display device according to claim 7, wherein the array substrate comprises a conductive structure located in the pin bonding area; the display device further comprises a protective layer, the protective layer covers the conductive structure and is located in a partial area of the pin bonding area, and the second adhesive layer covers the protective layer and the array substrate in the pin bonding area.

9. The display device according to claim 7, wherein the array substrate comprises a conductive structure located in the pin bonding area; the display device further comprises a protective layer, the protective layer covers the conductive structure and is located on an entirety of the pin bonding area, and the second adhesive layer is located between the protective layer and the decorative member.

10. The display device according to claim 1, wherein the array substrate comprises a conductive structure located in the pin bonding area; the display device further comprises a protective layer, and the protective layer covers the conductive structure and is located between the one or more support members and the array substrate.

11. The display device according to claim 10, further comprising an opposite substrate disposed opposite to the array substrate;
wherein a portion of the protective layer is located between the one or more support members and the opposite substrate.

12. The display device according to claim 10, wherein a thickness of the protective layer is less than a thickness of each of the one or more support members.

13. The display device according to claim 1, further comprising:
a plurality of flexible films bonded to the pin bonding area, wherein an orthographic projection of at least one of the one or more support members on the array substrate is between adjacent ones of the plurality of flexible films.

14. The display device according to claim 3, wherein at least one of the plurality of flexible films is located between the array substrate and one of the one or more support members.

15. The display device according to claim 14, wherein the support members comprise a first support member and a second support member, the first support member is located on the at least one flexible film, and the second support member is located between adjacent ones of the plurality of flexible films.

16. The display device according to claim 1, further comprising:
an opposite substrate disposed opposite to the array substrate; and
a first polarizer attached to a surface of the opposite substrate facing away from the array substrate;
wherein the pin bonding area extend outwardly relative to the opposite substrate, and the decorative member is further attached to the surface of the opposite substrate facing away from the array substrate and is spliced with the first polarizer.

17. The display device according to claim 16, further comprising:
a coating layer disposed on a surface of the decorative member facing away from the one or more support members, and a color of the coating layer is same as a color of a surface of the first polarizer facing away from the array substrate.

18. The display device according to claim 17, wherein a sum of a thickness of the decorative member and a thickness of the coating layer is equal to a thickness of the first polarizer.

19. The display device according to claim 16, wherein a thickness of each of the one or more support members is less than a thickness of the opposite substrate.

20. The display device according to claim 1, wherein the decorative member comprises a strip-like body portion, and the strip-like body portion is fixed to the one or more support members and shields the pin bonding area.
